(19) United States
(12) Patent Application Publication
(10) Pub. No.: US 2006/0261491 A1
(43) Pub. Date: Nov. 23, 2006

(54) Semiconductor device and method for manufacturing the same

(75) Inventors: Kaoru Soeta, Tokyo (JP); Daisuke Takai, San Jose, CA (US)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 11/436,178

(22) Filed: May 17, 2006

(30) Foreign Application Priority Data
May 18, 2005 (JP) 2005-145243

(51) Int. Cl. H01L 23/52

(52) U.S. Cl. 257/777

(57) ABSTRACT

The present invention relates to a semiconductor device and a method for manufacturing the same that prevent deformation or cracking caused by a difference in coefficient of thermal expansion. Elastic contacts provided on upper and lower surfaces of an interposer are elastically biased against the relatively displaced electrodes. The interposer thus compensates for displacement caused by different coefficients of thermal expansion so that an electrical connection between the electrodes of the first electronic component and the electrodes of the second electronic component is constantly maintained. Accordingly, this prevents separation or cracking in electrode connection areas.

### BACKGROUND OF THE INVENTION

1. Field of the Invention

The present invention relates to semiconductor devices and methods for manufacturing the same. In particular, the present invention relates to a semiconductor device and a method for manufacturing the same that prevent deformation or cracking caused by a difference in coefficient of thermal expansion so as to ensure a proper electrical connection between electronic components or between an electronic component and a base substrate.

2. Description of the Related Art

In the field of semiconductor devices in recent years, a technology of densification is developing by means of stacking a plurality of bare chips (electronic components) in a single package. There are several known packaging techniques for connecting electrodes of the plurality of bare chips to electrodes of a base substrate on which the bare chips are mounted. For example, such packaging techniques include a wire-bonding packaging technique in which the electrodes are connected using gold wires, a flip-chip packaging technique in which the bare chips are flipped over to face downward so that the electrodes are connected via bumps provided on the functional faces of the bare chips, and a stacked packaging technique in which the electrodes are connected via bumps provided in the bare chips having a multilayered structure. These packaging techniques are discussed in, for example, Japanese Unexamined Patent Application Publication No. 11-274375.

According to Japanese Unexamined Patent Application Publication No. 11-274375, the chips are formed using, for example, an underfill material and/or a die-bond material. Moreover, a substrate, the die-bond material, the underfill material, and a sealing resin material have predetermined relationships among one another in view of coefficient of thermal expansion and glass-transition temperature so as to reduce stress induced as a result of thermal stress and to prevent connection failures in soldered areas caused by, for example, separation or cracking.

Manufacturing a semiconductor device using the known packaging techniques mentioned above has the following problems.

Since a matching inspection for the above-referenced semiconductor device is easily affected by line impedance between the electrodes, the inspection must be performed in an end-product state, which means that all of the bare chips have to be set in predetermined positions and be in an electrically connected state. Therefore, even in a case where only some of the bare chips are mismatched, all of the bare chips will be determined to be defective. In other words, the semiconductor device, which is the end product, will be determined to be defective, meaning that the entire semiconductor device has to be discarded. This is problematic in that the yield rate is lowered, thus resulting in high manufacturing costs.

If only the mismatched bare chips can be replaced with new ones, the other bare chips do not need to be discarded. An ability to achieve this can prevent a waste of bare chips and thus contributes to lower manufacturing costs.

However, a process for separating at least one of the bare chips from the other bare chips, which are physically connected to each other with, for example, wires or electrically conductive adhesives, is extremely complicated, and thus leads to high manufacturing costs.

Moreover, Japanese Unexamined Patent Application Publication No. 11-274375 does have any descriptions related to materials that satisfy conditions with regard to coefficient of thermal expansion and glass-transition temperature, or in other words, has no detailed examples with regard to the substrate, the die-bond material, the underfill material, the sealing resin material, an electrically conductive adhesive, and so on. Therefore, even though the invention set forth in Japanese Unexamined Patent Application Publication No. 11-274375 may be theoretically correct, the semiconductor device according to such an invention is impractical and is actually difficult to manufacture.

### SUMMARY OF THE INVENTION

Accordingly, it is an object of the present invention to provide a semiconductor device that allows for a matching inspection during a manufacturing process thereof in a state similar to the actual end product of the device.

Furthermore, it is another object of the present invention to provide a semiconductor device and a method for manufacturing the device in which, if a mismatch of bare chips is determined in an inspection step during a manufacturing process, at least one of the mismatched bare chips (electronic components) can be readily replaced with a new one.

Furthermore, it is another object of the present invention to provide a semiconductor device that compensates for displacement caused by a difference in coefficient of thermal expansion between the bare chips or between the bare chips and a base substrate so as to prevent separation or cracking in electrode connection areas.

According to one aspect of the present invention, a semiconductor device includes an electronic component provided with a plurality of electrodes; a base substrate having a plurality of pattern electrodes disposed on a surface thereof; and an interposer whose upper and lower surfaces are both provided with a plurality of elastic contacts, the elastic contacts on the upper surface being electrically connected to the elastic contacts on the lower surface. The electrodes of the electronic component are electrically connected to the pattern electrodes of the base substrate via the interposer.

In this aspect of the present invention, the elastic contacts are elastically biased against the electrodes instead of being fixed to the electrodes. Consequently, even in a case where the positional relationship between the elastic contacts and the electrodes is subject to relative displacement due to a difference in coefficient of thermal expansion, the elastic contacts can be slid against the electrodes so as to be continuously elastically biased against the electrodes. Thus, the electrical connection between the elastic contacts and the electrodes can be maintained.

Furthermore, the semiconductor device may further include at least one electronic component stacked above the electronic component, such that the at least one electronic component of an upper layer and the electronic component of a lower layer are electrically connected to each other via an interposer disposed therebetween.

Accordingly, the electrodes of the at least one electronic component of the upper layer are constantly electrically connected to the electrodes of the electronic component of the lower layer.

For example, the interposer may include an insulating base having a plurality of through holes, and electric conductors embedded in the through holes. The elastic contacts are preferably disposed on opposite end surfaces of electric conductors.

In this case, the base is preferably composed of silicon or polyimide.

Accordingly, the coefficient of thermal expansion of the base is the same as or similar to those of the electronic component and the base substrate, thereby reducing relative displacement of the electrodes.

Furthermore, the elastic contacts on the upper surface of the interposer may be elastically biased against the electrodes of the electronic component disposed above the interposer or against electrodes provided in the at least one electronic component disposed above the interposer, and the elastic contacts on the lower surface of the interposer may be elastically biased against the pattern electrodes of the base substrate or against the electrodes of the electronic component disposed below the interposer.

Furthermore, the electronic component and the interposer are preferably fixed to each other with a first thermosetting or thermoplastic adhesive member disposed therebetween, and the interposer and the base substrate are preferably fixed to each other with a second thermosetting or thermoplastic adhesive member disposed therebetween.

Accordingly, this ensures the connection between the electrodes and the elastic contacts.

For example, the elastic contacts include spiral contact members or stressed metal members.

A lower surface of the base substrate may be provided with an external connection electrode.

According to another aspect of the present invention, a method for manufacturing a semiconductor device includes a first step for stacking at least two electronic components above a base substrate so as to form layers while mounting interposers and thermosetting or thermoplastic adhesive members between the adjacent layers, the at least two electronic components being provided with electrodes and the base substrate being provided with pattern electrodes, each interposer having opposite surfaces provided with a plurality of elastic contact's, the pattern electrodes and the electrodes being temporarily electrically connected via the elastic contacts, the electrodes being temporarily electrically connected to each other via the elastic contacts; a second step for implementing a matching inspection between the at least two electronic components by receiving an electric signal from an external source; and a third step for heating the adhesive members so as to fixedly bond the at least two electronic components together and/or fixedly bond the at least two electronic components to the base substrate.

Furthermore, if the matching between the at least two electronic components is determined to be defective in the second step, one of the at least two electronic components is preferably replaced with a new electronic component before repeating the first step.

According to the present invention, even in a case where the positional relationship between the elastic contacts and the electrodes is subject to relative displacement caused by a difference in coefficient of thermal expansion, the elastic contacts can be slid against the electrodes so as to be continuously elastically biased against the electrodes. Accordingly, this prevents separation or cracking in the electrode connection areas, whereby the electrical connection between the elastic contacts and the electrodes can be properly maintained.

Furthermore, since the matching inspection is incorporated into the manufacturing process, a combination of mismatched electronic components is prevented before the electronic components are fixedly bonded to each other. Accordingly, this contributes to a higher yield rate of the semiconductor device, which is the end product.

### BRIEF DESCRIPTION OF THE DRAWINGS

FIG. 1 is a cross-sectional view of a semiconductor device according to an exemplary embodiment of the present invention;

FIG. 2 is an enlarged cross-sectional view of a relevant portion of FIG. 1;

FIG. 3 is an enlarged cross-sectional view of a relevant portion of FIG. 2 and shows a first embodiment of the present invention;

FIG. 4 is a partially enlarged view corresponding to FIG. 3 and shows a state of thermal expansion;

FIG. 5 is a partial cross-sectional view similar to FIG. 3 and illustrates stressed metal members according to a second embodiment of the present invention;

FIG. 6 is a cross-sectional view illustrating a state where electronic components and interposers are alternately stacked one on top of the other above a base substrate; and

FIG. 7 is a flow chart of a manufacturing process for an electronic module corresponding to a manufacturing method according to the present invention.

### DESCRIPTION OF THE PREFERRED EMBODIMENTS

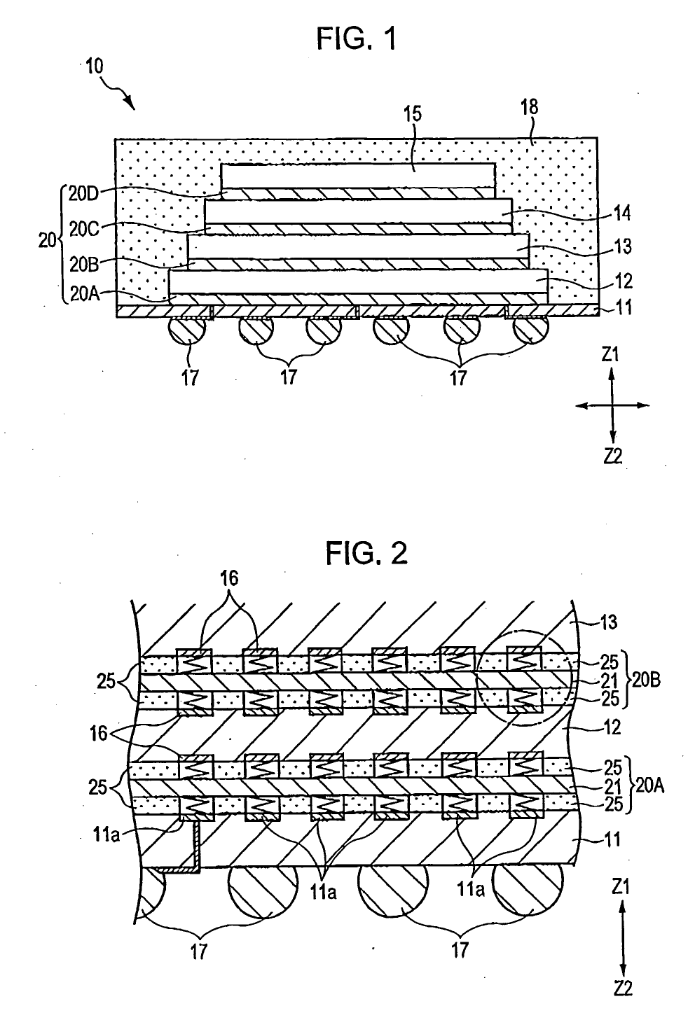

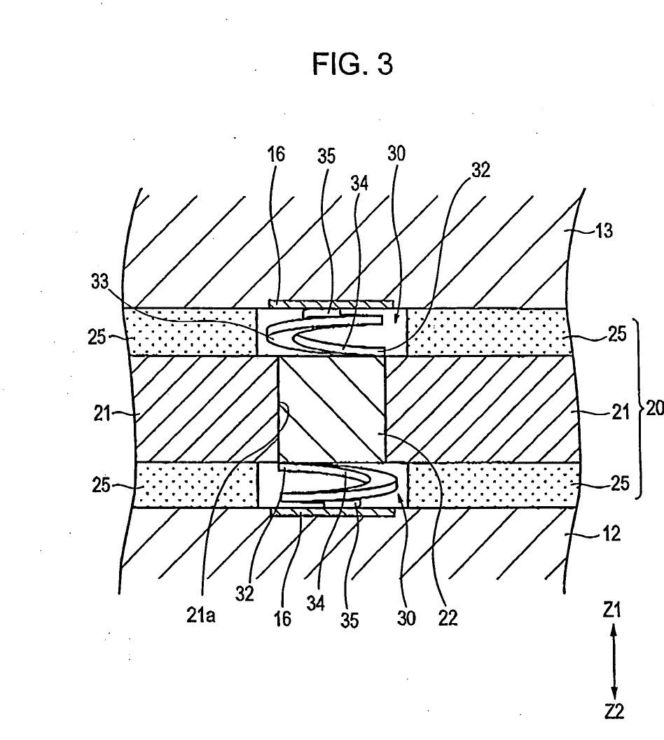

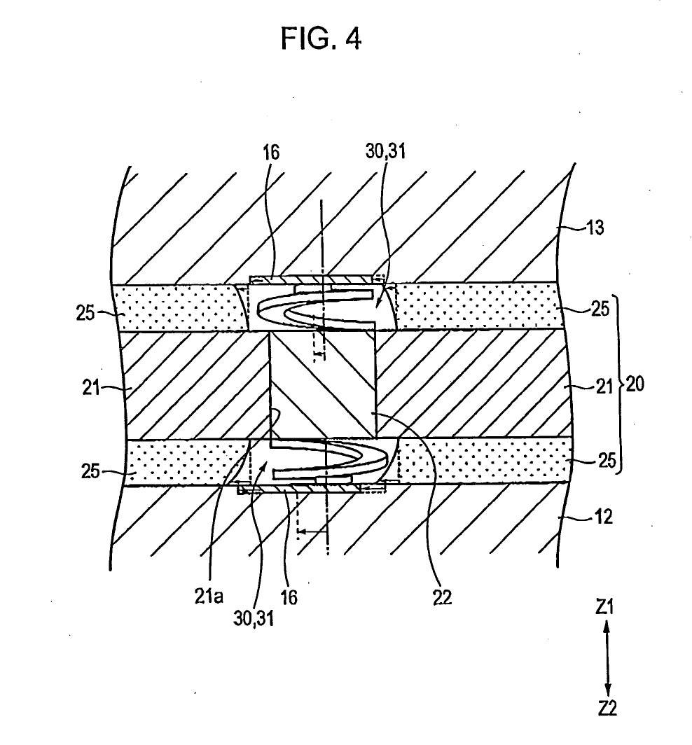

FIG. 1 is a cross-sectional view of a semiconductor device 10 according to an exemplary embodiment of the present invention. FIG. 2 is an enlarged cross-sectional view of a relevant portion of FIG. 1. FIG. 3 is a cross-sectional view of a relevant portion of FIG. 2 and shows spiral contact members according to a first embodiment of the present invention. FIG. 4 is a partially enlarged view corresponding to FIG. 3 and shows a state of thermal expansion.

The semiconductor device 10 shown in FIG. 1 is packaged in a single unit, and is provided with a base substrate 11 at the bottommost position of the device 10 in a direction of an arrow Z2. The semiconductor device 10 has a multilayer structure in which a plurality of electronic components 12, 13, 14, 15, such as semiconductor bare chips (which will be referred to as bare chips hereinafter), are stacked one on top of the other above the base substrate 11 in a height direction (Z) of the device 10.

Referring to FIG. 2, at least one of upper and lower surfaces of each of the electronic components 12, 13, 14, 15 is provided with a plurality of power-supply and signal input-output electrodes 16. The surfaces provided with the electrodes 16 serve as functional faces of the electronic components 12, 13, 14, 15.

The electronic components 12, 13, 14, 15 may alternatively be, for example, a Chip Scale Package (CSP) having substantially the same dimension as the bare chips. The electronic components 12, 13, 14, 15 are surrounded and sealed by a sealing material (mold resin) 18.

The base substrate 11 has a multilayer structure in which insulating layers composed of, for example, glass epoxy or polyimide and conductor layers are alternately stacked one on top of the other. The upper surface (top surface) of the base substrate 11 has a plurality of pattern electrodes 11a exposed thereon. The lower surface (bottom surface) of the base substrate 11 has external connection electrodes 17 arranged substantially in a matrix, such as a Ball Grid Array (BGA). The pattern electrodes 11a are electrically connected to the external connection electrodes 17 via the conductor layers in the multilayer base substrate 11. The base substrate 11 is rewired such that a pitch between the adjacent external connection electrodes 17 on the lower surface of the base substrate 11 is larger than a pitch between the adjacent pattern electrodes 11a on the upper surface.

Referring to FIG. 1, the electronic components 12, 13, 14, 15 and the base substrate 11 are respectively separated by interposers 20. Specifically, the base substrate 11 at the bottommost position and the electronic component 12 disposed thereabove are separated by an interposer 20A, and the electronic component 12 and the electronic component 13 disposed thereabove are separated by an interposer 20B. Similarly, the electronic component 13 and the electronic component 14 disposed thereabove are separated by an interposer 20C, and the electronic component 14 and the electronic component 15 disposed thereabove are separated by an interposer 20D.

Referring to FIG. 2, each of the interposers 20 according to the exemplary embodiment has a sheet-like base 21 formed of a material having a coefficient of thermal expansion that is the same as or similar to those of the electronic components 12, 13, 14, 15 and the base substrate 11. The upper and lower surfaces of each base 21 are provided with a plurality of elastic contacts 30, 30. The bases 21 are preferably composed of, for example, silicon or polyimide.

The first embodiment shown in FIG. 3 is directed to an example in which spiral contact members are used as the elastic contacts 30. In the first embodiment, the base 21 of each interposer 20 is provided with a plurality of through holes 21a at positions corresponding to the pattern electrodes 11a or the electrodes 16. Each through hole 21a has an electric conductor 22 embedded therein, which is composed of, for example, copper. The electric conductors 22 in the first embodiment are substantially columnar. The upper and lower end surfaces of each electric conductor 22 are respectively provided with spiral contact members 31.

Referring to FIG. 3, each spiral contact member 31 has a flat stationary portion 32 disposed at an outer periphery position and having a predetermined thickness, and an elastic arm portion 33 extending integrally from the stationary portion 32. The elastic arm portion 33 has a second end 34 adjoining the stationary portion 32 and a first end 35 positioned substantially in the center of the spiral pattern in plan view. The elastic arm portion 33 of the spiral contact member 31 is formed three-dimensionally such that the first end 35 extends away from the stationary portion 32. Therefore, when an external force is applied to the spiral contact member 31 in directions indicated by arrows Z1 and Z2 in the drawings, the elastic arm portion 33 becomes elastically deformed in the directions of the arrows Z1 and Z2. In each spiral contact member 31, an undersurface of the stationary portion 32 is fixed to the corresponding end surface of the electric conductor 22 with, for example, an electrically conductive adhesive.

The spiral contact members 31 may be formed by, for example, etching or plating. If an etching technique is applied, a thin plate-like copper film is etched into the shape shown in FIG. 3, and is then plated with, for example, nickel or a nickel-phosphorous alloy for reinforcement. Alternatively, the spiral contact members 31 may be formed of a laminate including copper and nickel layers or a laminate including copper and nickel-phosphorous alloy layers. In that case, nickel or a nickel-phosphorous alloy gives elasticity to the spiral contact members 31, whereas copper reduces the resistivity of the spiral contact members 31.

On the other hand, if a plating technique is applied, the spiral contact members 31 may be formed with copper layers. Alternatively, the spiral contact members 31 may be formed by depositing copper and nickel layers on top of each other by continuous plating, or by depositing copper and nickel-phosphorous layers on top of each other by continuous plating.

Referring to FIGS. 2 and 3, each interposer 20 and its adjacent electronic components or the base substrate 11 are bonded to each other with adhesive members 25. For example, the base substrate 11 and the interposer 20A are bonded to each other with one of adhesive members 25 disposed therebetween, and the interposer 20A and the electronic component 12 are bonded to each other with another adhesive member 25 disposed therebetween, and so on.

The adhesive members 25 may be formed of, for example, a thermosetting or thermoplastic adhesive film or adhesive paste, such as a non-conductive film (NCF) or a non-conductive paste (NCP). If the adhesive members 25 are formed of sheet-like adhesive films, each film is provided with a plurality of through holes that correspond to the plurality of spiral contact members 31 defining the elastic contacts 30.

Accordingly, each spiral contact member 31 is in a contracted state, such that the first end 35 serving as a contact is constantly elastically pressed against the corresponding electrode 16. For example, the electrodes 16 of the lower electronic component 12 and the electrodes 16 of the upper electronic component 13 respectively facing each other across the interposer 20B are electrically connected to each other via the spiral contact members 31 on the upper side of the interposer 20B, the spiral contact members 31 on the lower side of the interposer 20B, and the electric conductors 22 disposed between the upper and lower spiral contact members 31 of the interposer 20B.

As mentioned above, the bases 21, the electronic components 12, 13, 14, 15, and the base substrate 11 are composed of materials having the same or similar coefficient of thermal expansion. For example, in a case where the ambient temperature surrounding the semiconductor device 10 changes and thus induces deformation of the electronic components 12, 13, 14, 15, the interposers 20, and the base substrate 11, the positional relationship between the pattern electrodes 11a and the spiral contact members 31 and between the electrodes 16 and the spiral contact members 31 may be subject to relative displacement, as shown in FIG. 4. Even in that case, the first ends 35 of the spiral contact members 31 can be slid against the displaced pattern electrodes 11a or electrodes 16 so as to be continuously elastically biased against the pattern electrodes 11a or the electrodes 16 even after the sliding. Thus, the electrical connection between the electrodes 16 of the lower electronic component 12 and the electrodes 16 of the upper electronic component 13, for example, can constantly be maintained. Accordingly, the spiral contact members 31 compensate for the displacement caused by a difference in coefficient of thermal expansion, thereby preventing defective electrical continuity caused by separation or cracking in the electrode connection areas.

The positional relationship mentioned above applies similarly to the relationship among the base substrate 11, the interposer 20A, and the electronic component 12.

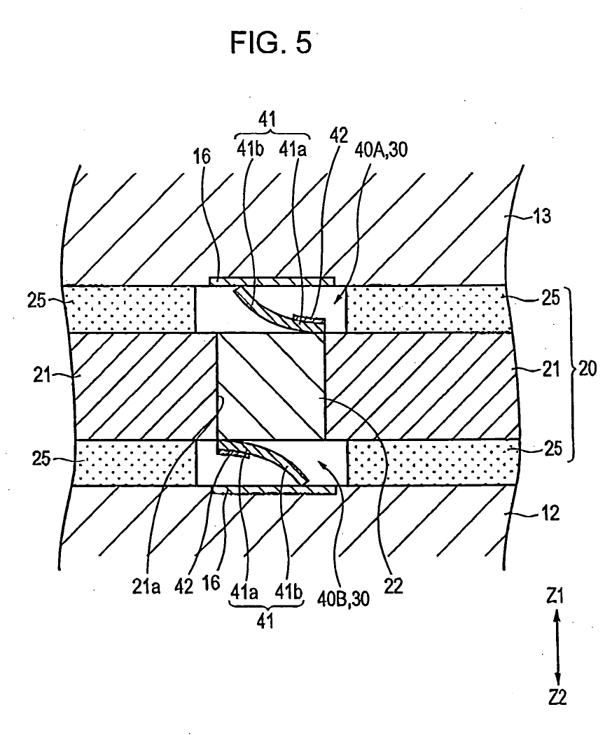

A second embodiment of the present invention will now be described with reference to FIG. 5.

FIG. 5 is a partial cross-sectional view similar to FIG. 3 and illustrates stressed metal members according to the second embodiment of the present invention.

The second embodiment shown in FIG. 5 is directed to an example in which stressed metal members 40 are used as the elastic contacts 30. Other configurations in the second embodiment are substantially the same as those in the first embodiment.

Each of the stressed metal members 40 includes a bent conductive contact strip 41. The contact strip 41 has a stationary portion 41a and an elastically deformable portion 41b. One of the surfaces of the stationary portion 41a is provided with a sacrificial layer 42. The sacrificial layer 42 may either be conductive or insulative. For example, the sacrificial layer 42 may be, for example, a resin layer mixed with Ti or conductive filler.

The contact strip 41 is coated with a conductive metal film (not shown) of, for example, Au. The metal film is formed by, for example, plating. A section of the metal film on the stationary portion 41a functions as a bonding layer to the corresponding end surface of the electric conductor 22. For example, an undersurface (i.e. bonding surface) of the stationary portion 41a of the contact strip 41 is securely bonded to the corresponding end surface of the electric conductor 22 via the metal film by, for example, ultrasonic welding.

Referring to FIG. 5, each elastically deformable portion 41b is bent to form a curve in the height direction of the stationary portion 41a. In other words, the elastically deformable portion 41b is bent so as to extend away from the corresponding end surface of the electric conductor 22. Accordingly, the elastically deformable portion 41b, which is a free end portion of the stressed metal member 40, is elastically deformable in the directions of the arrows Z1, Z2 with respect to the stationary portion 41a as being a fulcrum.

The bending characteristic of the elastically deformable portion 41b is achieved by giving different internal stresses to different internal sections of the elastically deformable portion 41b in a predetermined manufacturing step. In detail, for a stressed metal member 40A provided on the upper side of each interposer 20, one surface (upper surface) of the elastically deformable portion 41b is given a compressive stress, whereas the other surface (lower surface) is given a tensile stress. On the other hand, for a stressed metal member 40B provided on the lower side of each interposer 20, one surface (lower surface) of the elastically deformable portion 41b is given a compressive stress, whereas the other surface (upper surface) is given a tensile stress.

Accordingly, the elastically deformable portion 41b of the upper stressed metal member 40A is bent upward in FIG. 5, whereas the elastically deformable portion 41b of the lower stressed metal member 40B is bent downward in FIG. 5.

Referring to FIG. 5, each interposer 20 and its adjacent electronic components or the base substrate 11 are bonded to each other with the adhesive members 25. For example, the base substrate 11 and the interposer 20A are bonded to each other with one of the adhesive members 25 disposed therebetween, and the interposer 20A and the electronic component 12 are bonded to each other with another adhesive member 25 disposed therebetween, and so on. The adhesive members 25 may be formed of, for example, a thermosetting or thermoplastic adhesive film or adhesive paste, such as NCF or NCP.

As the adhesive members 25 harden, the distance between the base substrate 11 and the interposer 20A and the distance between the interposer 20A and the electronic component 12 become smaller in comparison to the non-hardened state of the adhesive members 25. For this reason, each of the electrodes 16 of the upper electronic component 13 applies pressure to the free end (first end) of the corresponding stressed metal member 40A in the direction of the arrow Z2, thus allowing the stressed metal member 40A to be elastically deformed downward. Similarly, each of the electrodes 16 of the lower electronic component 12 applies pressure to the free end (first end) of the corresponding stressed metal member 40B in the direction of the arrow Z1, thus allowing the stressed metal member 40B to be elastically deformed upward.

Accordingly, the electrodes 16 of the upper electronic component 13 and the electrodes 16 of the lower electronic component 12 are electrically connected to each other via the stressed metal members 40A, the electric conductors 22, and the stressed metal members 40B.

In the second embodiment, the free ends (first ends) of the stressed metal members 40A and the stressed metal members 40B are constantly elastically biased against the respective electrodes 16, 16. Therefore, even in a case where deformation of the electronic components 12, 13, 14, 15, the interposers 20, and the base substrate 11 caused by a change in ambient temperature induces relative displacement in the positional relationship between the stressed metal members 40 and the electrodes 16, the free ends (first ends) of the stressed metal members 40 can be slid against the displaced electrodes 16 so as to be continuously elastically biased against the electrodes 16. Thus, the electrical connection between the electrodes 16 of the lower electronic component 12 and the electrodes 16 of the upper electronic component 13 can constantly be maintained. Accordingly, the stressed metal members 40 compensate for the displacement caused by a difference in coefficient of thermal expansion, thereby preventing defective electrical continuity caused by separation or cracking in the electrode connection areas. The positional relationship mentioned above applies similarly to the relationship among the base substrate 11, the interposer 20A, and the electronic component 12.

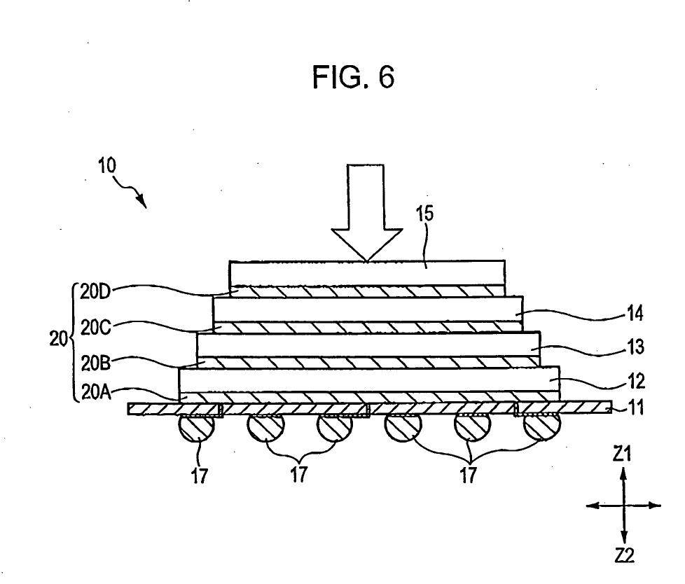

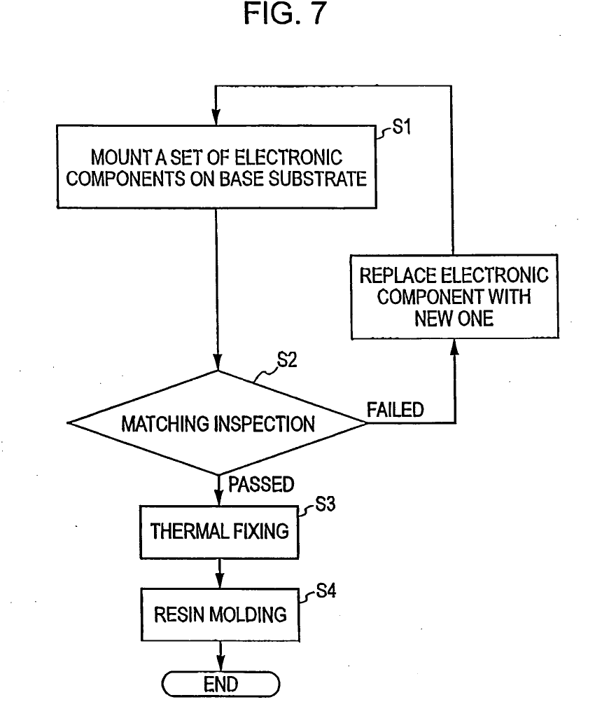

A method for manufacturing and inspecting the semiconductor device 10 equipped with the elastic contacts 30 described above will now be described with reference to FIGS. 6 and 7.

FIG. 6 is a cross-sectional view illustrating a state where the electronic components 12, 13, 14, 15 and the interposers 20 are alternately stacked one on top of the other above the base substrate 11. FIG. 7 is a flow chart of a manufacturing process for an electronic module corresponding to a manufacturing method according to the present invention.

In step S1, a set of electronic components 12, 13, 14, 15 and the interposers 20A, 20B, 20C, 20D constituting the semiconductor device 10 subject to inspection are stacked alternately in a predetermined order on the base substrate 11. In this step, the adhesive members 25 in a non-hardened state are respectively provided at predetermined positions between the interposers 20A, 20B, 20C, 20D and the electronic components 12, 13, 14, 15 and between the interposer 20A and the base substrate 11.

In FIG. 6, the electronic components 12, 13, 14, 15, the interposers 20A, 20B, 20C, 20D, and the adhesive members 25 are alternately stacked in a predetermined order. A load is applied to the uppermost electronic component 15 in the direction of the arrow Z2, such that the components constituting the semiconductor device 10 are temporarily secured. Thus, the elastic contacts 30 provided in the interposers 20A, 20B, 20C, 20D are elastically biased against the pattern electrodes 11a of the base substrate 11 and the electrodes 16 of the electronic components 12, 13, 14, 15. Accordingly, the electrodes 16 of an upper electronic component are electrically connected to the electrodes 16 of a lower electronic component or to the pattern electrodes 11a of the base substrate 11.

The temporal securing of the components mentioned above can be readily achieved using a designated maintaining member, such as a socket.

In step S2, the plurality of external connection electrodes 17 provided on the lower surface of the base substrate 11 is supplied with power and electric signals from an external source so as to implement a matching inspection among the set of electronic components 12, 13, 14, 15 included in the semiconductor device 10. The matching inspection may include, for example, continuity checking, an impedance matching inspection, an on-resistance measurement inspection between terminals, and a leakage-current inspection.

In step S3, the semiconductor device 10 that has passed the inspection is heated at a predetermined temperature for a predetermined time period. Then, the adhesive members 25 harden so that the base substrate 11 and the interposer 20A become fixedly bonded to each other and the electronic components 12, 13, 14, 15 and the interposers 20B, 20C, 20D also become fixedly bonded to each other. Due to thermal contraction of the adhesive members 25, the elastic contacts 30 contract accordingly, whereby the electrical connection between the first ends of the elastic contacts 30 and the electrodes 16 and the electrical connection between the first ends of the elastic contacts 30 and the pattern electrodes 11a are maintained.

In a case where the adhesive members 25 are formed of a thermoplastic adhesive material, each adhesive member 25 thermally contracts as it cools down from the heated state to room temperature. Thus, the distance between the base substrate 11 and the interposer 20A and the distance between the interposers 20 and the electronic components 12, 13, 14, 15 become smaller. Accordingly, this achieves a good connection state in which the electrodes 16 of the electronic components 12, 13, 14, 15 are constantly in contact with the corresponding elastic contacts 30.

In step S4, the semiconductor device 10 is entirely sealed with the sealing material 18 by resin molding so that an end product is attained. Since the semiconductor device 10 manufactured by this method has passed the matching inspection, the semiconductor device 10 can be shipped as a Known Good Die (KGD) product.

On the other hand, if the semiconductor device 10 fails the inspection in step S2, the operation returns to step S1 where, for example, the electronic component 15 of the set of electronic components 12, 13, 14, 15 is replaced with a new electronic component 15. Subsequently, the operation proceeds to step S2 where the matching inspection is implemented again.

If the semiconductor device 10 having the new set of electronic components 12, 13, 14, 15 passes the re-inspection, the electronic components 12, 13, 14, 15 are fixedly bonded to the interposers 20A, 20B, 20C, 20D and the base substrate 11 with the adhesive members 25 in step S3. Subsequently, the resin molding process is performed on the semiconductor device 10 in step S4. Since it is highly probable that the old electronic component 15 replaced with the new one is defective, the electronic component 15 may be discarded or may be subject to a more detailed inspection.

On the other hand, if the semiconductor device 10 fails the re-inspection step, it is highly probable that at least one of the electronic components 12, 13, and 14 is defective. In that case, for example, the electronic component 14 is replaced with a new one, and the same re inspection step is implemented again on the semiconductor device 10 with the new set of electronic components. If the semiconductor device 10 passes the re-inspection, the thermal-fixing process is performed on the semiconductor device 10 in step S3. Subsequently, the resin-molding process is performed on the semiconductor device 10 in step S4.

In the method for manufacturing the semiconductor device 10 according to the present invention, the matching inspection of the electronic components 12, 13, 14, 15 can be implemented in the assembled state thereof. Accordingly, this preliminarily prevents a combination of mismatched electronic components, thereby contributing to a higher yield rate of the semiconductor device 10 (i.e. the percentage of products manufactured in a manufacturing line from which defective products are subtracted).

Furthermore, even if a combination of electronic components is determined to be defective the first time, there is still a possibility that the combination of electronic components having at least one of the electronic components replaced with a new one may be determined to be non-defective in a re-inspection process. Therefore, only the electronic components that are determined to be defective in the final inspection may be discarded. Accordingly, this reduces the number of electronic components to be discarded, thereby contributing to a higher yield rate of the electronic components.

Although the spiral contact members 31 and the stressed metal members 40 are used as the elastic contacts 30 in the above embodiments, the present invention may include other alternatives for the elastic contacts 30. For example, such alternatives may include a membrane-type elastic contact having a metal film that forms a top layer and an elastic body composed of rubber or elastomer attached to a bottom surface of the metal film, an elastically deformable spring pin (contact pin) whose first end serving as a contact is bent into a substantially U-shape, a contact probe (see Japanese Unexamined Patent Application Publication No. 2002-357622), and a volute spring.

What is claimed is:

1. A semiconductor device comprising:
an electronic component provided with a plurality of electrodes:
a base substrate having a plurality of pattern electrodes disposed on a surface thereof; and
an interposer whose upper and lower surfaces are both provided with a plurality of elastic contacts, the elastic contacts on the upper surface being electrically connected to the elastic contacts on the lower surface,
wherein the electrodes of the electronic component are electrically connected to the pattern electrodes of the base substrate via the interposer.

2. The semiconductor device according to claim 1, further comprising at least one electronic component stacked above the electronic component, said at least one electronic component of an upper layer and the electronic component of a lower layer are electrically connected to each other via an interposer disposed there between.

3. The semiconductor device according to claim 1, wherein the interposer includes an insulating base having a plurality of through holes, and electric conductors embedded in the through holes, and wherein the elastic contacts are disposed on opposite end surfaces of the electric conductors.

4. The semiconductor device according to claim 3, wherein the base is composed of silicon or polyimide.

5. The semiconductor device according to claim 1, wherein the elastic contacts on the upper surface of the interposer are elastically biased against the electrodes of the electronic component disposed above the interposer, and the elastic contacts on the lower surface of the interposer are elastically biased against the pattern electrodes of the base substrate.

6. The semiconductor device according to claim 2, wherein the elastic contacts on the upper surface of the interposer are elastically biased against electrodes provided in said at least one electronic component disposed above the interposer, and the elastic contacts on the lower surface of the interposer are elastically biased against the electrodes of the electronic component disposed below the interposer.

7. The semiconductor device according to claim 1, wherein the electronic component and the interposer are fixed to each other with a first thermosetting or thermoplastic adhesive member disposed therebetween, and the interposer and the base substrate are fixed to each other with a second thermosetting or thermoplastic adhesive member disposed therebetween.

8. The semiconductor device according to claim 1, wherein the elastic contacts comprise spiral contact members or stressed metal members.

9. The semiconductor device according to claim 1, wherein a lower surface of the base substrate is provided with an external connection electrode.

10. A method for manufacturing a semiconductor device, comprising:
a first step for stacking at least two electronic components above a base substrate so as to form layers while mounting interposers and thermosetting or thermoplastic adhesive members between the adjacent layers, said at least two electronic components being provided with electrodes and the base substrate being provided with pattern electrodes, each interposer having opposite surfaces provided with a plurality of elastic contacts, the pattern electrodes and the electrodes being temporarily electrically connected via the elastic contacts, the electrodes being temporarily electrically connected to each other via the elastic contacts:
a second step for implementing a matching inspection between said at least two electronic components by receiving an electric signal from an external source; and
a third step for heating the adhesive members so as to fixedly bond said at least two electronic components together and/or fixedly bond said at least two electronic components to the base substrate.

11. The method for manufacturing the semiconductor device according to claim 10, wherein if the matching between said at least two electronic components is determined to be defective in the second step, one of said at least two electronic components is replaced with a new electronic component before repeating the first step.
